(19) United States
(12) Patent Application Publication
(10) Pub. No.: US 2025/0096193 A1
(43) Pub. Date: Mar. 20, 2025

(54) METHODS OF BONDING SEMICONDUCTOR ELEMENTS TO SUBSTRATES

(71) Applicant: Kulicke and Soffa Industries, Inc., Fort Washington, PA (US)

(72) Inventors: Adeel Ahmad Bajwa, Blue Bell, PA (US); Thomas J. Colosimo, JR., West Chester, PA (US)

(73) Assignee: Kulicke and Soffa Industries, Inc., Fort Washington, PA (US)

(21) Appl. No.: 18/825,559

(22) Filed: Sep. 5, 2024

Related U.S. Application Data
(60) Provisional application No. 63/539,284, filed on Sep. 19, 2023.

(51) Int. Cl. H01L 23/00

(52) U.S. Cl. CPC H01L 24/81; H01L 2224/8102; H01L 2224/81048; H01L 2224/81065; H01L 2224/81097

(57) ABSTRACT

A method of bonding a semiconductor element to a substrate is provided. The method includes the steps of: (a) providing the semiconductor element at a position separated from the substrate, the semiconductor element including a plurality of conductive structures, each of the conductive structures including a contact portion; (b) heating the semiconductor element at the position such that the contact portions are in a molten state; and (c) bonding the semiconductor element to the substrate such that each of the contact portions is bonded to a corresponding conductive structure of the substrate.

### CROSS-REFERENCE TO RELATED APPLICATION

This application claims the benefit of U.S. Provisional Application No. 63/539,284, filed Sep. 19, 2023, the content of which is incorporated herein by reference.

### FIELD

The invention relates to bonding systems and processes, and more particularly, to improved systems and methods for bonding a semiconductor element to a substrate.

### BACKGROUND

Traditional semiconductor packaging typically involves die attach processes and wire bonding processes. Advanced semiconductor packaging technologies (e.g., flip chip bonding, thermocompression bonding, etc.) technologies continue to gain traction in the industry. For example, in thermocompression bonding (i.e., TCB), heat and/or pressure (and sometimes ultrasonic energy) are used to form a plurality of interconnections between (i) electrically conductive structures on a semiconductor element and (ii) electrically conductive structures on a substrate. In certain flip chip bonding or thermocompression bonding applications, the electrically conductive structures of the semiconductor element and/or the substrate may include surface oxides that can impair bond quality.

Thus, it would be desirable to provide improved methods of bonding semiconductor elements to a substrate (e.g., which reduce oxides and/or improve bond quality).

### SUMMARY

According to an exemplary embodiment of the invention, a method of bonding a semiconductor element to a substrate is provided. The method includes the steps of: (a) providing the semiconductor element at a position separated from the substrate, the semiconductor element including a plurality of conductive structures, each of the conductive structures including a contact portion; (b) heating the semiconductor element at the position such that the contact portions are in a molten state; and (c) bonding the semiconductor element to the substrate such that each of the contact portions is bonded to a corresponding conductive structure of the substrate.

According to other embodiments of the invention, the method recited in the immediately preceding paragraph may have any one or more of the following features: further including a step of providing a deoxidizing agent in contact with the contact portions prior to step (c); further including a step of providing a deoxidizing agent in contact with the contact portions prior to step (b); further including a step of providing a deoxidizing agent in contact with the contact portions during step (b); further including a step of providing a deoxidizing agent in contact with the contact portions after step (b); the deoxidizing agent (of any of the preceding steps) includes at least one of a reducing gas and a plasma gas; the deoxidizing agent (of any of the preceding steps) includes a reducing gas, the reducing gas including formic acid; further including a step of cooling the semiconductor element after step (b) such that the contact portions are in a solid state just prior to step (c); the position is a post-alignment position; and/or further including a step of heating the conductive structures of the substrate prior to step (c).

According to another exemplary embodiment of the invention, a method of bonding a semiconductor element to a substrate is provided. The method includes the steps of: (a) providing the semiconductor element at a position separated from the substrate, the semiconductor element including a plurality of conductive structures, each of the conductive structures including a contact portion; (b) heating the semiconductor element at the position such that the contact portions are at a temperature within 40° C. of a melting point of a material of the contact portions, the temperature being below the melting point; and (c) bonding the semiconductor element to the substrate such that each of the contact portions is bonded to a corresponding conductive structure of the substrate.

According to other embodiments of the invention, the method recited in the immediately preceding paragraph may have any one or more of the following features: further including a step of providing a deoxidizing agent in contact with the contact portions prior to step (c); further including a step of providing a deoxidizing agent in contact with the contact portions prior to step (b); further including a step of providing a deoxidizing agent in contact with the contact portions during step (b); further including the step of providing a deoxidizing agent in contact with the contact portions after step (b); the deoxidizing agent (of any of the preceding steps) includes at least one of a reducing gas and a plasma gas; the deoxidizing agent (of any of the preceding steps) includes a reducing gas, the reducing gas including formic acid; further including a step of cooling the semiconductor element after step (b); the position is a post-alignment position; further including a step of heating the conductive structures of the substrate prior to bonding; step (b) includes heating the semiconductor element at the position such that the contact portions are within 30° C. of the melting point; step (b) includes heating the semiconductor element at the position such that the contact portions are within 20° C. of the melting point; and/or step (b) includes heating the semiconductor element at the position such that the contact portions are within 10° C. of the melting point.

According to yet another exemplary embodiment of the invention, a method of bonding a semiconductor element to a substrate is provided. The method includes the steps of: (a) providing the semiconductor element at a position separated from the substrate, the semiconductor element including a plurality of conductive structures; (b) heating the semiconductor element at the position to an increased temperature; (c) cooling the semiconductor element after step (b) to a reduced temperature below the increased temperature; and (d) bonding the semiconductor element to the substrate such that each of the conductive structures is bonded to a corresponding conductive structure of the substrate.

According to other embodiments of the invention, the method recited in the immediately preceding paragraph may have any one or more of the following features: further including a step of providing a deoxidizing agent in contact with the conductive structures prior to step (d); further including a step of providing a deoxidizing agent in contact with the conductive structures prior to step (b); further including a step of providing a deoxidizing agent in contact with the conductive structures during step (b); further including a step of providing a deoxidizing agent in contact with the conductive structures after step (b); the deoxidizing agent (of any of the preceding steps) includes at least one of a reducing gas and a plasma gas; the deoxidizing agent (of any of the preceding steps) includes a reducing gas, the reducing gas including formic acid; the position is a post-alignment position; further including a step of heating the conductive structures of the substrate prior to bonding; the conductive structures of the semiconductor element include copper; the conductive structures of the substrate include copper; the conductive structures of the substrate include copper; and/or no solder is provided between the conductive structures and the corresponding conductive structures of the substrate during step (d).

According to yet another exemplary embodiment of the invention, a method of bonding a semiconductor element to a substrate is provided. The method includes the steps of: (a) providing the semiconductor element at a position separated from the substrate, the semiconductor element including a plurality of conductive structures, each of the conductive structures including a contact portion; (b) providing a deoxidizing agent in contact with the contact portions; (c) heating the semiconductor element at the position such that the contact portions are in a molten state; (d) cooling the semiconductor element after step (c) such that the contact portions are in a solid state; and (e) bonding the semiconductor element to the substrate after step (d) such that each of the contact portions is bonded to a corresponding conductive structure of the substrate.

According to other embodiments of the invention, the method recited in the immediately preceding paragraph may have any one or more of the following features: step (b) occurs prior to step (e); step (b) occurs prior to step (c); step (d) occurs after step (c) such that the contact portions are in a solid state just prior to step (e); the position is a post-alignment position; further including a step of heating the conductive structures of the substrate prior to bonding; the deoxidizing agent includes at least one of a reducing gas and a plasma gas; and/or the deoxidizing agent includes a reducing gas, the reducing gas including formic acid.

### BRIEF DESCRIPTION OF THE DRAWINGS

The invention is best understood from the following detailed description when read in connection with the accompanying drawings. It is emphasized that, according to common practice, the various features of the drawings are not to scale. On the contrary, the dimensions of the various features are arbitrarily expanded or reduced for clarity. Included in the drawings are the following figures:

FIGS. 1A-1I are a series of block diagrams of a bonding system, illustrating a method of bonding a semiconductor element to a substrate in accordance with various exemplary embodiments of the invention;

FIGS. 2A-2J are a series of block diagrams of the bonding system of FIGS. 1A-1J, illustrating another method of bonding a semiconductor element to a substrate in accordance with another exemplary embodiment of the invention;

FIGS. 3A-3J are a series of block diagrams of the bonding system of FIGS. 1A-1J, illustrating another method of bonding a semiconductor element to a substrate in accordance with another exemplary embodiment of the invention;

FIGS. 4-7 are flow diagrams illustrating various methods of bonding a semiconductor element to a substrate in accordance with various exemplary embodiments of the invention; and

FIG. 8 is a block diagram of another bonding system in accordance with another exemplary embodiment of the invention.

### DETAILED DESCRIPTION

Provided herein are various methods of bonding a semiconductor element to a substrate. Both substrates (e.g., a target substrate) and semiconductor elements (e.g., a die, a “chip”, etc.) may have various oxides with varying degrees of oxide thickness which may cause bond quality issues. Certain embodiments provided herein may mitigate issues associated with such oxides and may provide more effective and uniform cleaning, as compared to known bonding processes. Certain embodiments of the invention may accelerate a rate of oxide reduction on electrically conductive surfaces to be bonded. For example, oxides on conductive structures of a semiconductor element (e.g., “chip-side”) may be reduced in a thermocompression bonding (TCB) process (e.g., a fluxless TCB process).

In certain TCB processes, a semiconductor element (e.g., a source die) may be brought to an appropriate distance (e.g., 1-2 mm) away from a target substrate. A deoxidizing agent (e.g., a reducing gas, a formic acid vapor, plasma, plasma gas, etc.) may be provided (e.g., injected) at or near the semiconductor element and/or the target substrate. At the same time, the semiconductor element may be heated such that contact portions (e.g., including solder) of the conductive structures are heated above a melting temperature of a material included in/on the contact portions (e.g., solder). When the contact portions are in a molten state in the presence of certain deoxidizing agents (e.g., formic acid vapor), a rate of oxide reduction increases. Contact portions that are in a molten state may be configured to absorb certain amounts of surface oxides. In certain embodiments, the effects of oxide reduction and oxide absorption compound/combine and result in a particularly effective cleaning process. In certain embodiments, molten solder may be solidified before contacting corresponding conductive structures (e.g., “target bumps”) of the substrate. In certain embodiments, contact during bonding may be made when the contact portions are in a molten state.

When cleaned conductive structures (e.g., “die bumps”) of the semiconductor element contact the substrate, the conductive structures may act as a heat transfer medium. Consequently, heat from the semiconductor element transfers (e.g., “flows”) through the conductive structures of the substrate and may clean surface oxides (e.g., oxide/formate layers) present on the substrate. Embodiments of the invention may provide improved cleaning on both chip and substrate sides as compared to known bonding processes, which may greatly improve bond quality. Certain embodiments of the invention may enable pre-cleaning process steps to be avoided, such as pre-cleaning process steps for the substrate.

As used herein, the term “semiconductor element” is intended to refer to any structure including (or configured to include at a later step) a semiconductor chip or die. Exemplary semiconductor elements include a bare semiconductor die, a semiconductor die on a substrate (e.g., a leadframe, a PCB, a carrier, a semiconductor chip, a semiconductor wafer, a BGA substrate, a semiconductor element, etc.), a packaged semiconductor device, a flip chip semiconductor device, a die embedded in a substrate, a stack of semiconductor die, amongst others. Further, the semiconductor element may include an element configured to be bonded or otherwise included in a semiconductor package (e.g., a spacer to be bonded in a stacked die configuration, a substrate, etc.).

As used herein, the term “substrate” is intended to refer to any structure to which a semiconductor element may be bonded. Exemplary substrates include, for example, a leadframe, a PCB, a carrier, a module, a semiconductor chip, a semiconductor wafer, a BGA substrate, another semiconductor element, etc.

In accordance with certain exemplary embodiments of the invention, a fluxless bonding system is provided using a deoxidizing agent (e.g., a reducing gas). The bonding system may be, for example, a flip chip bonding system, a thermocompression bonding system, a thermosonic bonding system, etc.

Certain embodiments are best described in connection with the drawings. Throughout the various drawings, like reference numerals refer to the like elements, except where explained herein. Shading, hatching, and/or patterning in the drawings may be used to indicate a heightened temperature; however, such shading, hatching, and/or patterning is arbitrary and is not necessarily intended to be mean the same temperature across the various drawings.

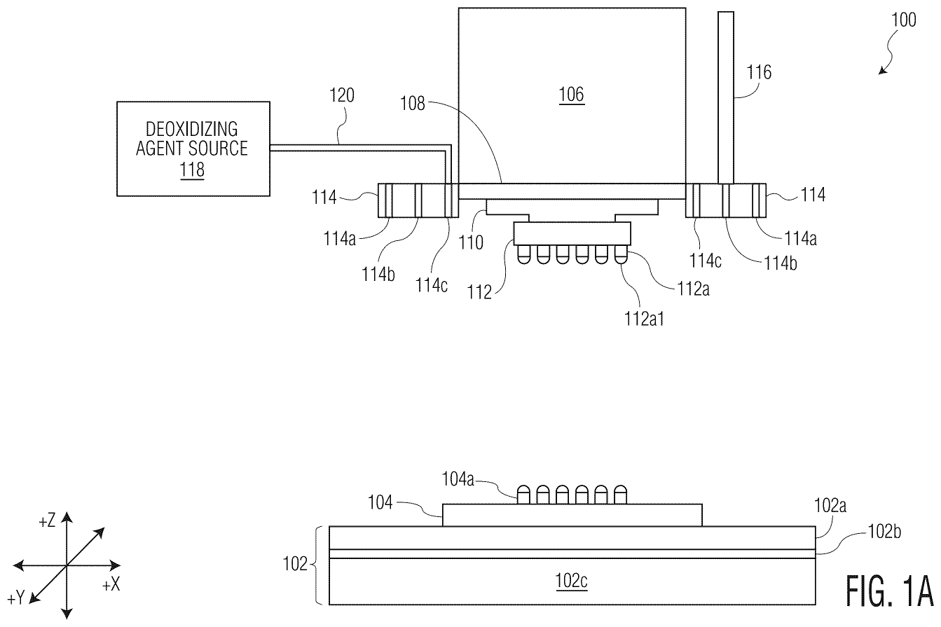

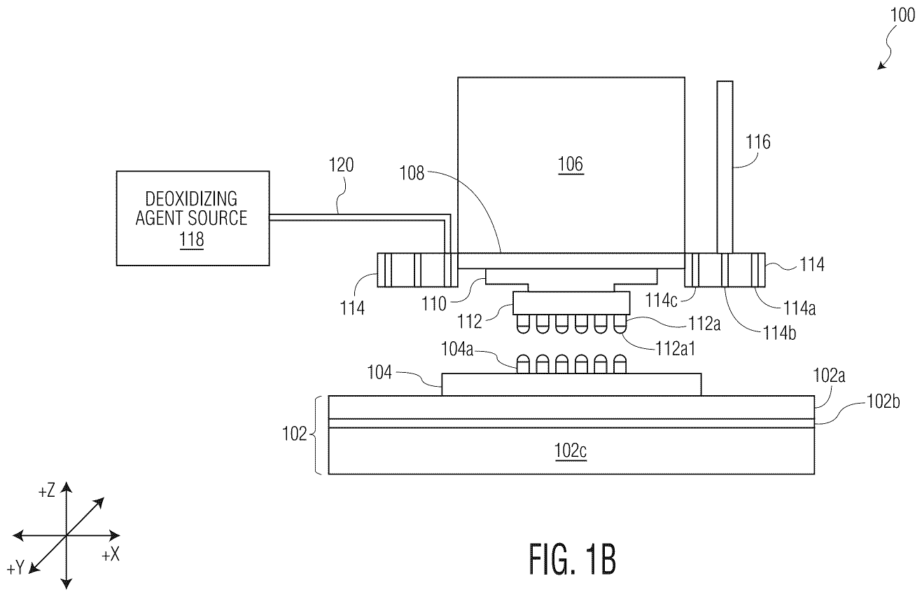

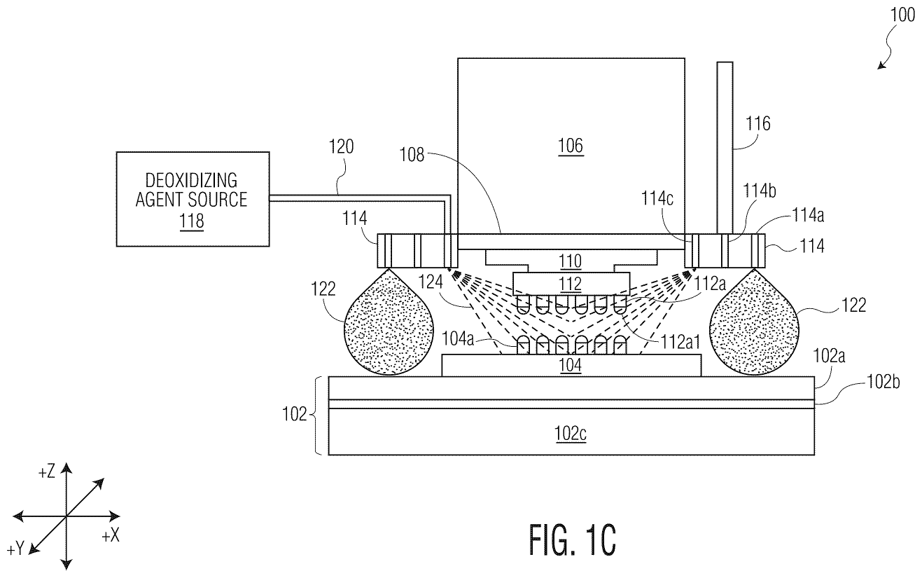

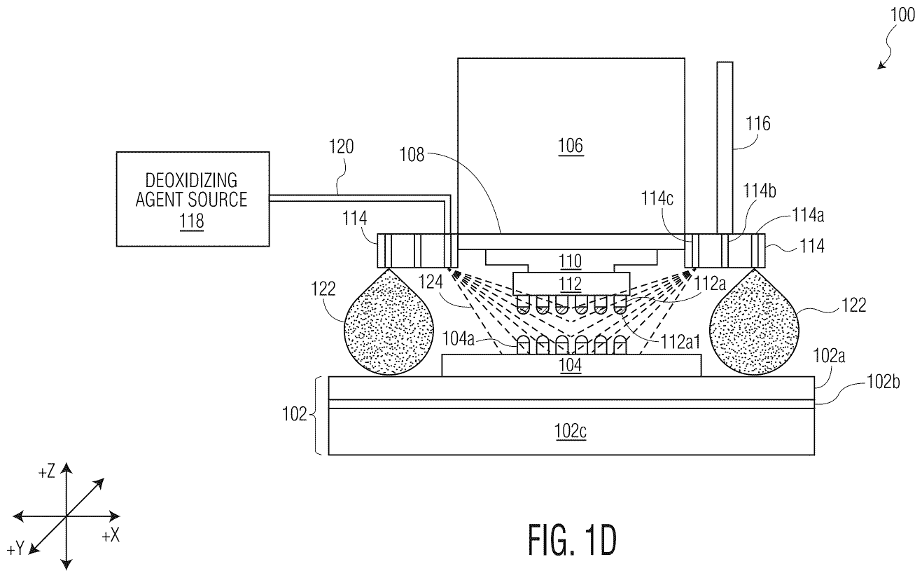

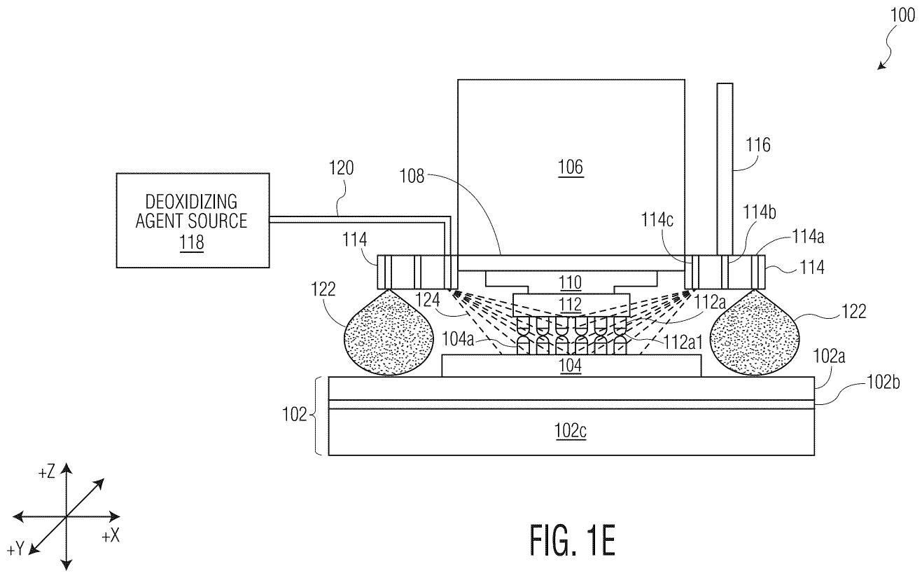

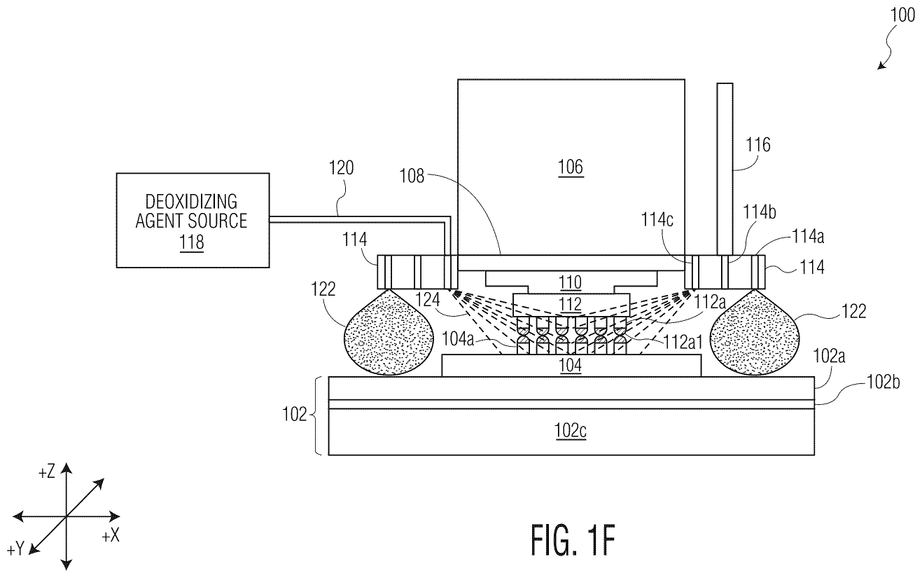

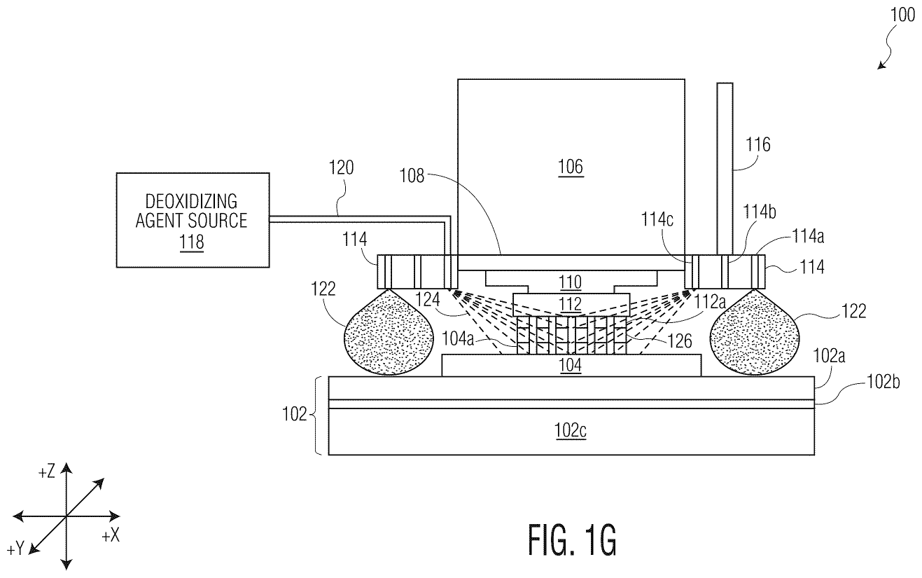

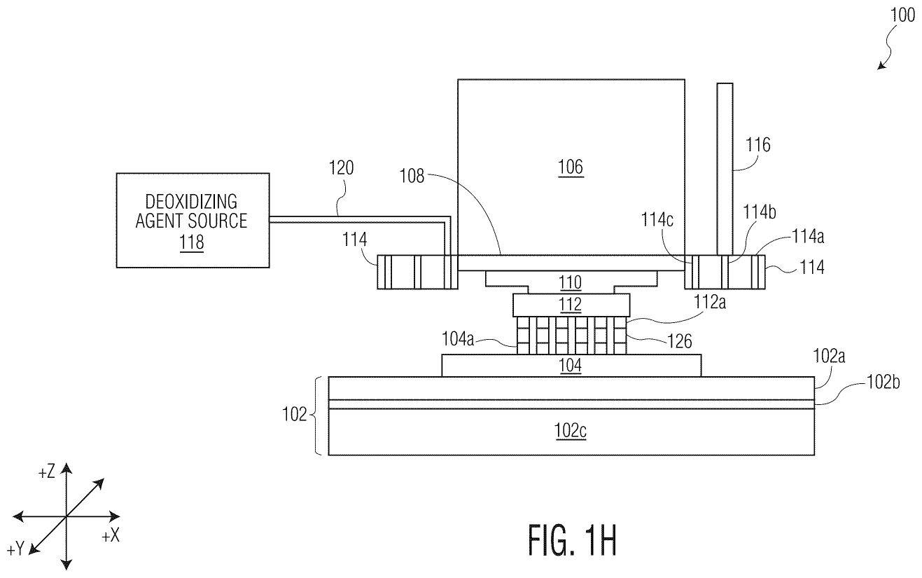

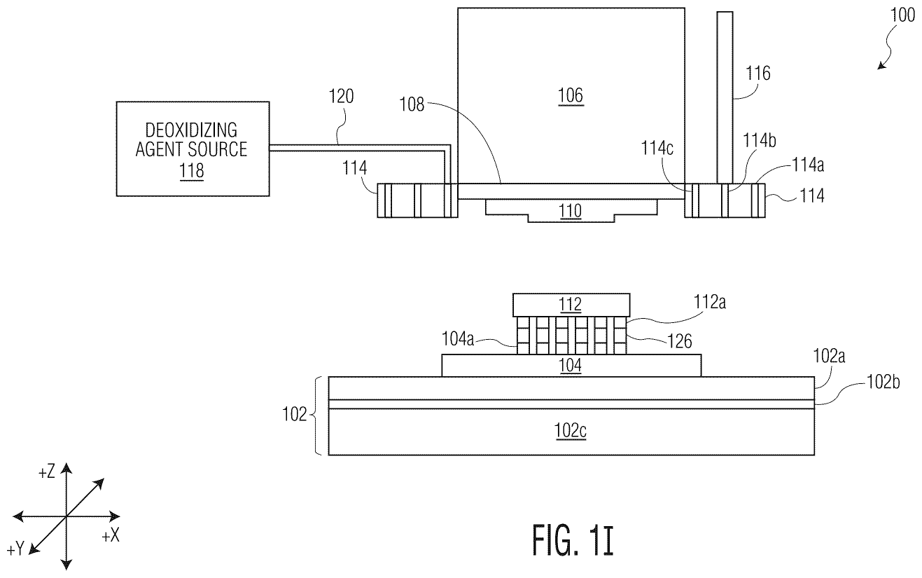

Referring now to FIGS. 1A-1I, FIGS. 2A-2J, and FIGS. 3A-3J, a bonding machine 100 (e.g., a flip chip bonding machine, a thermocompression bonding machine, etc.) is illustrated in connection with certain exemplary embodiments of the invention. Bonding machine 100 includes a bond head assembly 106, which may be configured to move along (and about) a plurality of axes of bonding machine 100 (e.g., the x-axis, y-axis, z-axis, a rotative/theta axis, etc.). Bond head assembly 106 includes a heater 108 and a bonding tool 110. In certain embodiments, heater 108 and/or bonding tool 110 can include gas channels configured to supply a cooling fluid (e.g., a gas, forced gas, forced air, nitrogen, etc.) to cool a semiconductor element. In certain bonding machines (e.g., thermocompression bonding machines) it may be desirable to heat bonding tool 110. Thus, while FIGS. 1A-1I illustrate a separate heater 108 for heating bonding tool 110 (e.g., for heating semiconductor element 112/112′ including a plurality of electrically conductive structures 112a/112b and/or a plurality of contact portions 112a1), it will be appreciated that heater 108 and bonding tool 110 may be integrated into a single element (e.g., a heated bonding tool).

Bond head assembly 106 carries a bond head manifold 114 for receiving and distributing fluids (e.g., deoxidizing agents, gases, liquids, vapors, plasmas, etc.) as desired in a given application. As used herein, the terms “fluid” and “gas” are intended to be broadly construed (e.g., including referring to a state of matter without a fixed shape and/or is capable of flowing). In accordance with certain exemplary embodiments of the invention, bonding systems (e.g., fluxless bonding systems) may provide a “gas” for reducing oxides on conductive structures of a substrate and/or a semiconductor element. Such a gas may include a carrier gas (e.g., nitrogen, argon, etc.), where such a carrier gas may be a mixture of gases (e.g., nitrogen and hydrogen mix, etc.). For example, the gas may be a reducing gas (e.g., formic acid vapor, acetic acid vapor), a plasma gas (e.g., including a carrier gas such as nitrogen), a gas including attached electrons (e.g., including a carrier gas such as a nitrogen and hydrogen mix), etc.

As illustrated, bond head manifold 114 is illustrated connected to a deoxidizing agent source 118 (e.g., a bubbler system, a gas tank, a plasma source, etc.) via piping 120 (e.g., including hard piping, flexible tubing, a combination of both, or any other structure adapted to carry the deoxidizing agents and/or fluids described herein). In certain embodiments, deoxidizing agent source 118 may be a vapor generation system such as a bubbler type system including an acid fluid (e.g., formic acid, acetic acid, etc.). In certain embodiments, deoxidizing agent source 118 may be configured to supply a plasma gas to reduce or remove oxides (e.g., on semiconductor element 112/112′ and/or substrate 104/104′). For example, deoxidizing agent source 118 may be a plasma gas delivery system (or connected to a plasma gas delivery system).

Throughout the drawings, bond head manifold 114 is illustrated in a cross-sectional view; it should be understood the bond head manifold 114 may surround bonding tool 110 (e.g., bond head manifold 114 surrounding bonding tool 110 in a coaxial configuration). Bond head manifold 114 may have different configurations from that illustrated in the drawings. Further, it is understood that certain details of bond head manifold 114 (e.g., interconnection with piping 120, structural details for distributing a deoxidizing agent within bond head manifold 114, structural details for distributing a shielding gas within bond head manifold 114, structural details for drawing a vacuum through a center channel of bond head manifold 114, etc.) are omitted for simplicity.

Bond head manifold 114 includes three channels 114a, 114b, 114c having different functions. Outer channel 114a receives a shielding gas (e.g., an inert gas, a nitrogen gas, etc.) from a shielding gas supply (e.g., included in deoxidizing agent source 118 or fluidically connected with deoxidizing agent source 118). That is, a shielding gas is provided from a shielding gas supply (e.g., a nitrogen supply), through piping 120, to outer channel 114a of bond head manifold 114. From outer channel 114a of bond head manifold 114, a shielding gas 122 is provided as a shield from the outer environment. Inner channel 114c receives a deoxidizing agent 124 via piping 120, and provides a deoxidizing agent 124 to an area including semiconductor element 112/112′ and substrate 104/104′ in connection with a bonding operation.

As will be appreciated by those skilled in the art, the specific design of a bond head manifold (or a different delivery system for providing the deoxidizing agent) may vary considerably. For example, in certain embodiments of the invention, a shielding gas may not be provided by a bond head manifold. Likewise, in certain embodiments of the invention, an exhaust system local to the bond head manifold may not be utilized. For example, in a bonding system utilizing a plasma gas as the deoxidizing agent, such a shielding gas (and/or local exhaust system) may not be deemed critical, and thus may not be included in the bonding system.

Bonding machine 100 includes a support structure 102 for supporting a substrate 104/104′ during a bonding operation (where substrate 104/104′ includes a plurality of electrically conductive structures 104a/104b). Support structure 102 may include any appropriate structure for the specific application. Support structure 102 includes a top plate 102a (configured to directly support substrate 104/104′), a chuck 102c, and a heater 102b disposed therebetween. In applications where heat for heating substrate 104/104′ is desirable in connection with the bonding operation, a heater such as heater 102b may be utilized.

In connection with a bonding operation, semiconductor element 112/112′ is bonded to substrate 104/104′ using bonding tool 110. During the bonding operation, corresponding ones of electrically conductive structures of semiconductor element 112/112′ are bonded (e.g., using heat, force, ultrasonic energy, etc.) to respective ones of electrically conductive structures 104a/104b of substrate 104/104′. Bond head manifold 114 provides a deoxidizing agent 124 (e.g., a reducing gas including a saturated vapor gas) in the area of semiconductor element 112/112′ and substrate 104/104′ in connection with a bonding operation. After deoxidizing agent 124 is distributed in the area of semiconductor element 112/112′ and substrate 104/104′, deoxidizing agent 124 contacts surfaces of each of electrically conductive structures 112a/112b/104a/104b of semiconductor element 112/112′ and substrate 104/104′. The surfaces of electrically conductive structures 104a/112a may then include a reaction product (e.g., where the reaction product is provided as a result of (i) a surface oxide on electrically conductive structures 112a/112b/104a/104b, and (ii) deoxidizing agent 124 from deoxidizing agent source 118. This reaction product is desirably removed from the bonding area (i.e., the area where electrically conductive structures 112a/112b of semiconductor element 112/112′ are bonded to corresponding electrically conductive structures 104a/104b of substrate 104/104′) using a vacuum provided through center channel 114b of bond head manifold 114 via exit piping 116.

Referring specifically now to FIGS. 1A-1I, a bond head assembly 106 is illustrated positioning a semiconductor element 112 above a substrate 104 in FIG. 1A. Semiconductor element 112 includes a plurality of conductive structures 112a. As illustrated, each conductive structure 112a includes a contact portion 112a1 (e.g., a solder contact portion).

In FIG. 1B, semiconductor element 112 is lowered by bond head assembly 106 and provided at a position separated from substrate 104. Such a position may be considered (i) a post-alignment position, (ii) a pre-bonding position, or (iii) another position (e.g., a predetermined position) as desired.

In FIG. 1C, a bond head manifold 114 is illustrated providing a shielding gas 122 and a deoxidizing agent 124. Shielding gas 122 (e.g., an inert gas, a gas including nitrogen, etc.) is provided in an area surrounding semiconductor element 112 and substrate 104. Deoxidizing agent 124 is illustrated being distributed in proximity to a bonding area of semiconductor element 112 and substrate 104. Deoxidizing agent 124 may contact the surfaces of each of the electrically conductive structures 112a (including contact portions 112a1) of semiconductor element 112 and each of the electrically conductive structures 104a of substrate 104.

In FIG. 1D, contact portions 112a1 are illustrated at a higher temperature (as indicated by the shading of contact portions 112a1) as compared to contact portions 112a1 illustrated in FIG. 1C. In certain embodiments, contact portions 112a1 are in a molten state (e.g., where solder of contact portions 112a1 are in a liquid or melted state). In certain embodiments, contact portions 112a1 are in a semi-molten state (e.g., where the innermost solder of contact portions 112a1 is in a liquid or melted state). In certain embodiments, contact portions 112a1 are in a solid state (e.g., at a temperature below the melting point of a material of contact portions 112a1, such as within 40° C. (or 30° C., 20° C., or 10° C.) of the melting point).

In FIG. 1E, contact portions 112a1 are brought into contact with corresponding conductive structures 104a of substrate 104. Contact portions 112a1 are now illustrated at a lower temperature as compared to contact portions 112a1 illustrated in FIG. 1D. Conductive structures 104a of substrate 104 may act as a heatsink or cooling mechanism such that contact portions 112a1 are cooled. In certain embodiments, contact portions 112a1 may be solidified from a previously molten state.

In FIG. 1F, contact portions 112a1 are now illustrated at a higher temperature (as indicated by the shading of contact portions 112a1) as compared to contact portions 112a1 illustrated in FIG. 1E. Further, at least a portion of conductive structures 104a of substrate 104 are now illustrated at a higher temperature as compared to conductive structures 104a illustrated in FIG. 1E. In certain embodiments, heat may be provided from heater 108 and/or heater 102b. The elevated temperatures of contact portions 112a1, and of conductive structures 104a, tends to result in a metallurgical bond (e.g., resulting from solder reflow) being formed therebetween.

In FIG. 1G, semiconductor element 112 has now been bonded to substrate 104. That is, each contact portion 112a1 from FIG. 1F is illustrated having been bonded to a corresponding conductive structure 104a of substrate 112, thereby forming bonded portions 126. Thus, during the bonding operation, corresponding ones of electrically conductive structures 112a of semiconductor element 112 are bonded (e.g., using heat, force, ultrasonic energy, etc.) to respective ones of electrically conductive structures 104a of substrate 104. Although six conductive structures 112a of semiconductor element 112 are illustrated bonded to six conductive structures 104a of substrate 104, the invention is not so limited. It is understood that any number of conductive structures 112a can be bonded to any number of conductive structures 104a. For example, two or more conductive structures 112a can be bonded to one conductive structure 104a. In another example, two or more conductive structures 104a can be bonded to one conductive structure 112a.

In FIG. 1H, bond head manifold 114 is illustrated no longer providing deoxidizing agent 124 and shielding gas 122. In FIG. 1I, bond head assembly 106 is illustrated having been moved away (e.g., along the Z-axis) from support structure 102, with semiconductor element 112 now bonded to substrate 104.

FIGS. 1C-1G illustrate bond head manifold 114 providing deoxidizing agent 124 (e.g., a reducing gas, formic acid, plasma, plasma gas, etc.) and shielding gas 122 (e.g., an inert gas, a gas including nitrogen, etc.) continuously (i.e., prior to and during bonding). However, the invention is not so limited. For example, in certain embodiments, the deoxidizing agent may be provided in contact with contact portions 112a1 at various different times, for example: just prior to bonding; prior to heating contact portions 112a1; during heating contact portions 112a1; after heating contact portions 112a1; etc.

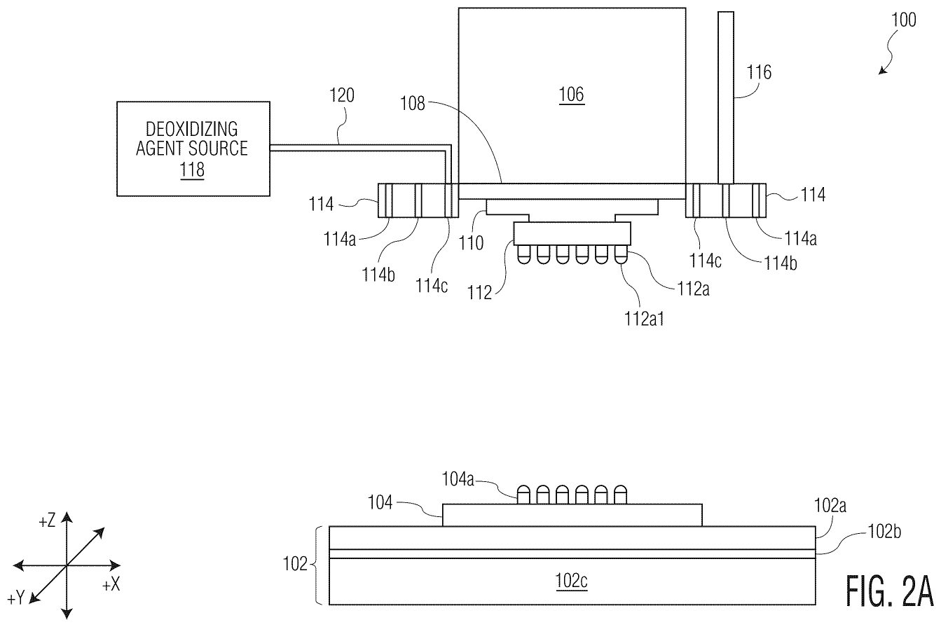

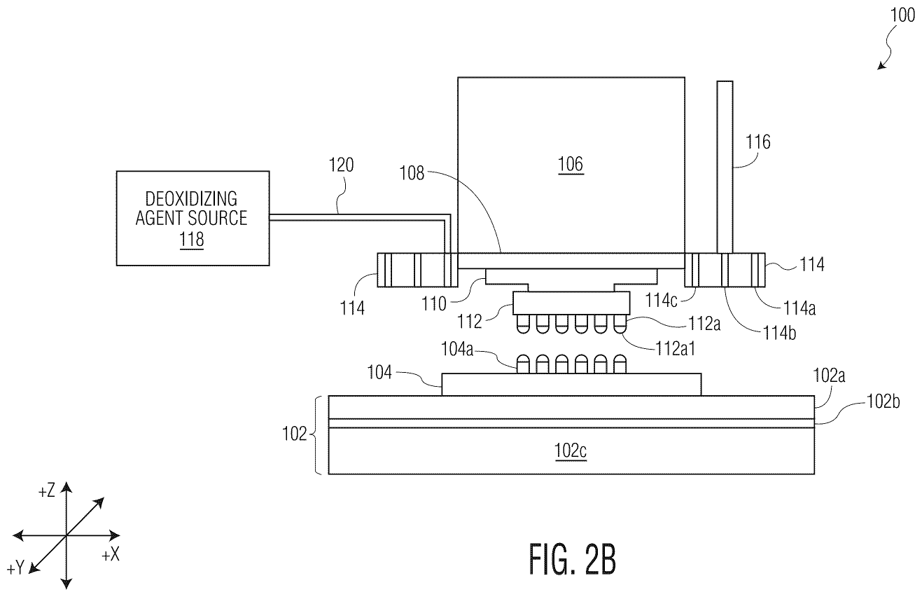

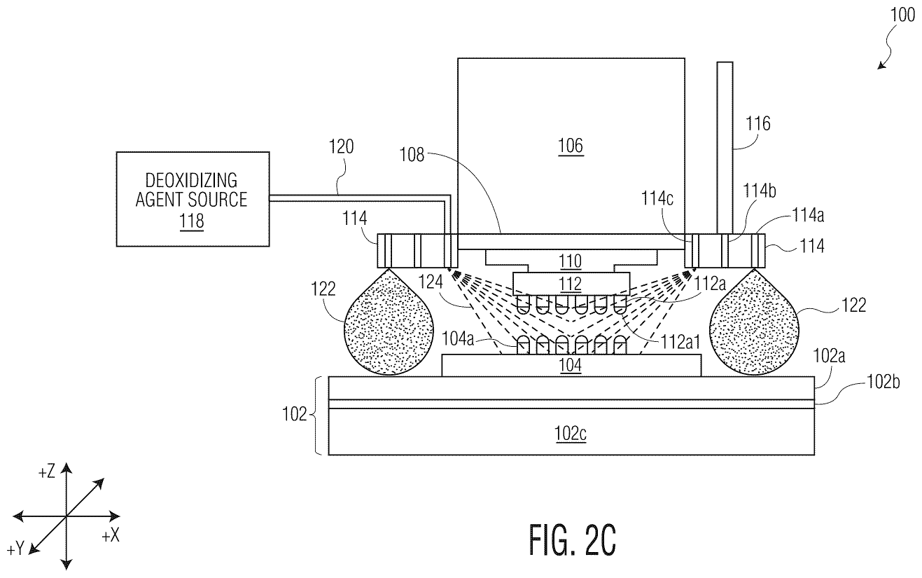

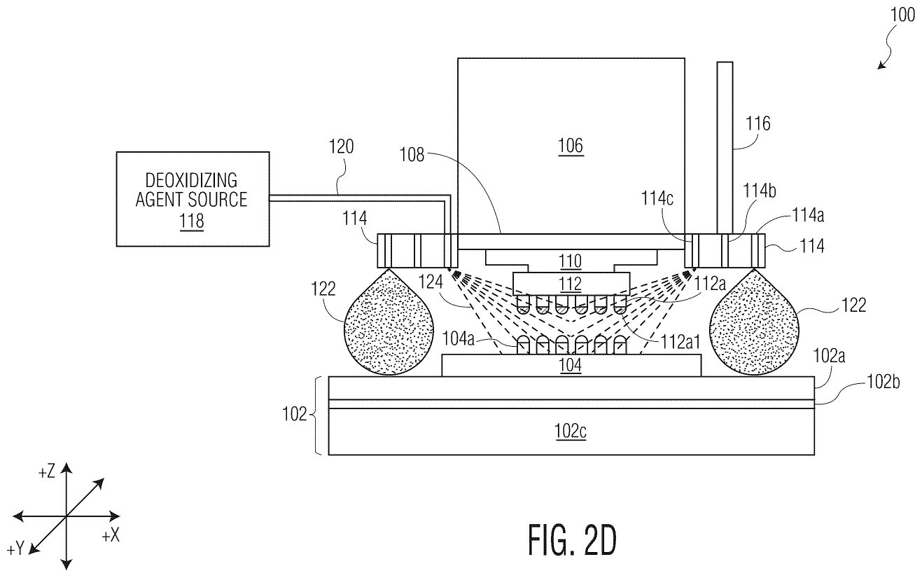

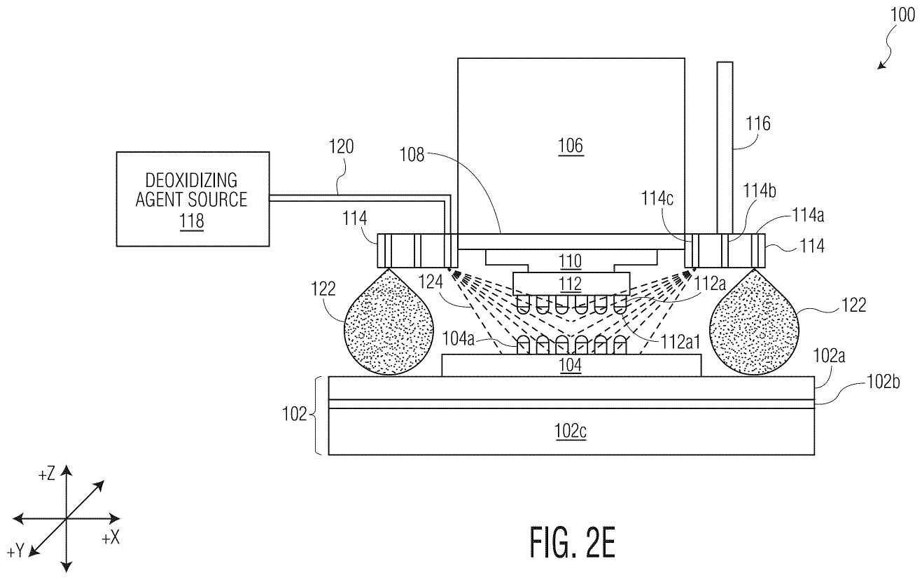

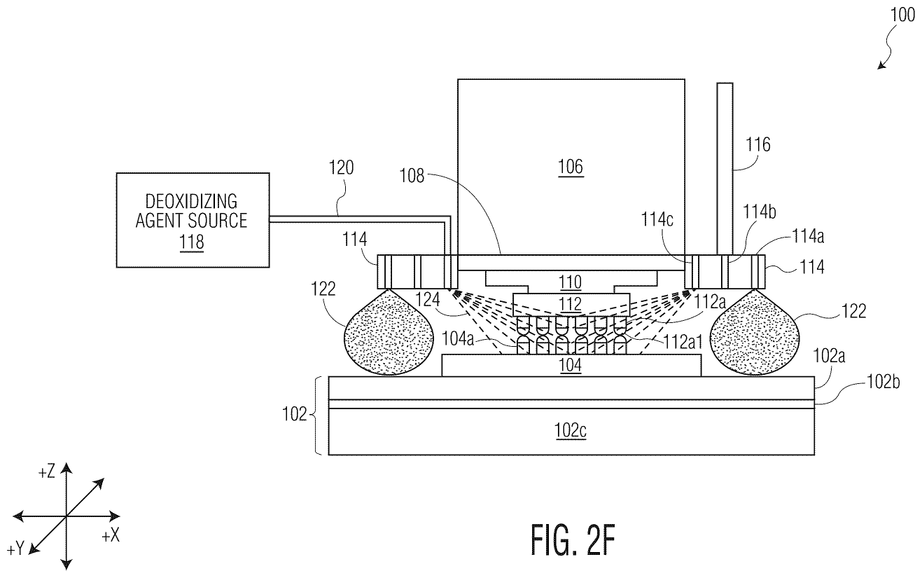

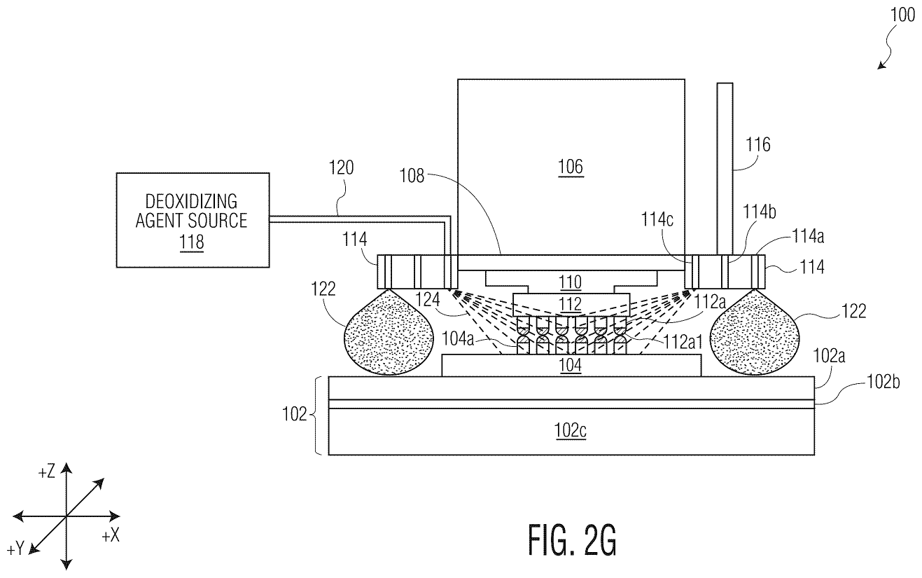

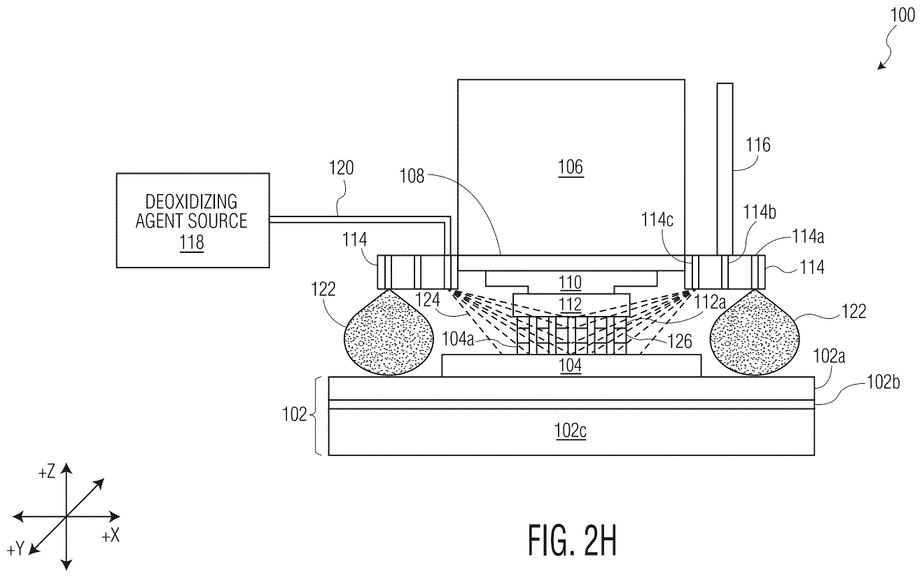

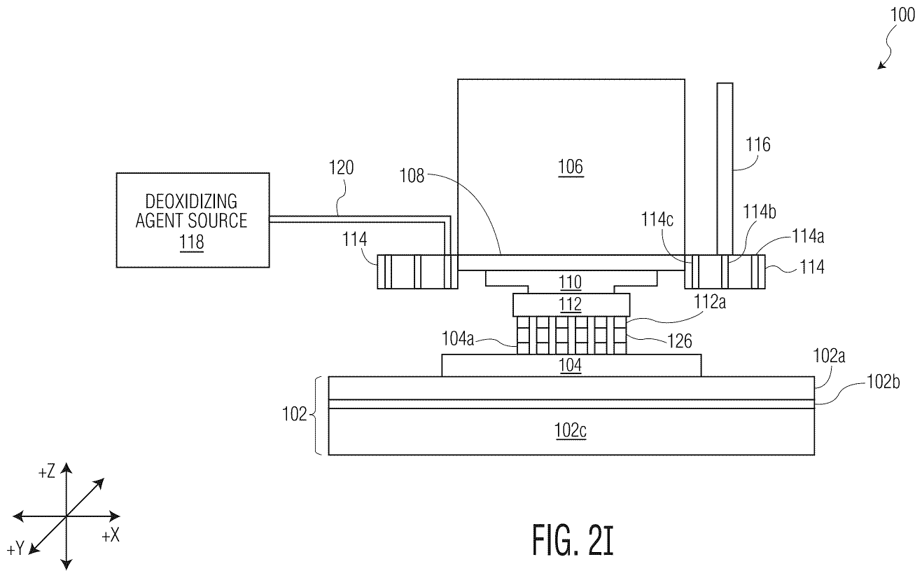

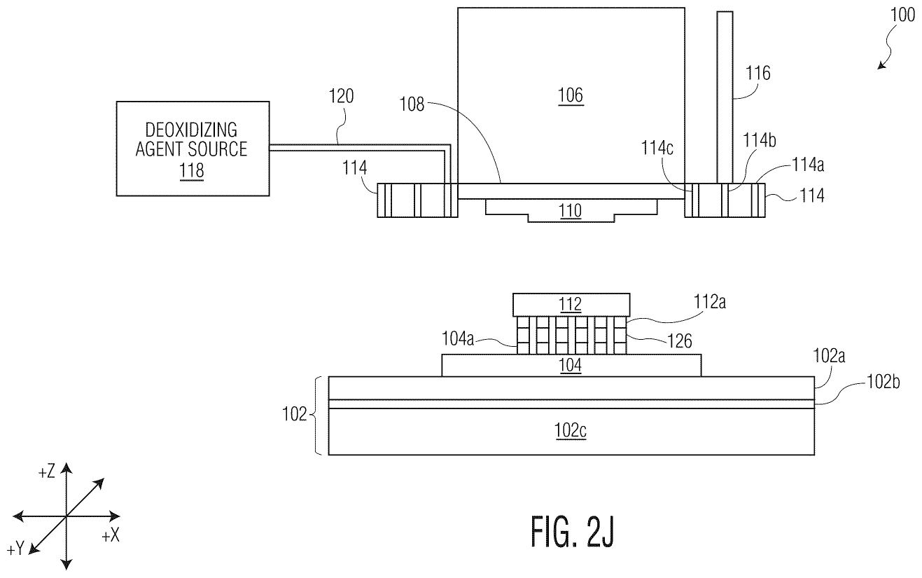

Referring now to FIGS. 2A-2J, another exemplary embodiment of the invention is illustrated. Referring specifically to FIG. 2A, bond head assembly 106 is illustrated positioning semiconductor element 112 above substrate 104. Semiconductor element 112 includes a plurality of conductive structures 112a. As illustrated, each conductive structure 112a includes a contact portion 112a1 (e.g., a solder contact portion).

In FIG. 2B, semiconductor element 112 is provided at a position separated from substrate 104. Such a position may be considered (i) a post-alignment position, (ii) a pre-bonding position, or (iii) another position (e.g., a predetermined position) as desired.

In FIG. 2C, bond head manifold 114 is illustrated providing shielding gas 122 and deoxidizing agent 124. Shielding gas 122 (e.g., an inert gas, a gas including nitrogen, etc.) is provided in an area surrounding semiconductor element 112 and substrate 104. Deoxidizing agent 124 is illustrated being distributed in proximity to a bonding area of semiconductor element 112 and substrate 104. Deoxidizing agent 124 may contact the surfaces of each of the electrically conductive structures 112a (including contact portions 112a1) of semiconductor element 112 and each of the electrically conductive structures 104a of substrate 104.

In FIG. 2D, contact portions 112a1 are illustrated at a higher temperature (as indicated by the shading of contact portions 112a1) as compared to contact portions 112a1 illustrated in FIG. 2C. In certain embodiments, contact portions 112a1 are in a molten state (e.g., where solder of contact portions 112a1 are in a liquid or melted state). In certain embodiments, contact portions 112a1 are in a semi-molten state (e.g., where the innermost solder of contact portions 112a1 is in a liquid or melted state). In certain embodiments, contact portions 112a1 are in a solid state (e.g., at a temperature below the melting point of a material of contact portions 112a1, such as within 40° C. (or 30° C., 20° C., or 10° C.) of the melting point).

In FIG. 2E, contact portions 112a1 are now illustrated at a lower temperature as compared to contact portions 112a1 illustrated in FIG. 2D. Accordingly, semiconductor element 112 (including conductive structures 112a) has now been cooled. In certain embodiments, semiconductor element 112 may be passively cooled (e.g., via turning off heater 108, via convection of adjacent gases, etc.) and/or actively cooled (e.g., via forced air, via forced gas from a gas channel of heater 108 and/or bonding tool 110, via a cooling mechanism, etc.). In certain embodiments, contact portions 112a1 are in a solid state (e.g., at a temperature below the melting point of a material of contact portions 112a1, such as within 40° C. of the melting point).

In FIG. 2F, contact portions 112a1 are brought into contact with corresponding conductive structures 104a of substrate 104. In certain embodiments, contact portions 112a1 may be at an even lower temperature as compared to contact portions 112a1 illustrated in FIG. 2E. Conductive structures 104a of substrate 104 may act as a heatsink or cooling mechanism such that contact portions 112a1 are further cooled.

In FIG. 2G, contact portions 112a1 are now illustrated at a higher temperature (as indicated by the shading of contact portions 112a1) as compared to contact portions 112a1 illustrated in FIG. 2F. Further, at least a portion of conductive structures 104a of substrate 104 are now illustrated at a higher temperature as compared to conductive structures 104a illustrated in FIG. 2F. In certain embodiments, heat may be provided from heater 108 and/or heater 102b. The elevated temperatures of contact portions 112a1, and of conductive structures 104a, tends to result in a metallurgical bond (e.g., resulting from solder reflow) being formed therebetween.

In FIG. 2H, semiconductor element 112 has now been bonded to substrate 104. Each of contact portions 112a1 from FIG. 2G is illustrated having been bonded to a corresponding conductive structure 104a of substrate 112, thereby forming bonded portions 126. During the bonding operation, corresponding ones of electrically conductive structures 112a of semiconductor element 112 are bonded (e.g., using heat, force, ultrasonic energy, etc.) to respective ones of electrically conductive structures 104a of substrate 104. Although six conductive structures 112a of semiconductor element 112 are illustrated bonded to six conductive structures 104a of substrate 104, the invention is not so limited. It is understood that any number of conductive structures 112a can be bonded to any number of conductive structures 104a. For example, two or more conductive structures 112a can be bonded to one conductive structure 104a. In another example, two or more conductive structures 104a can be bonded to one conductive structure 112a.

In FIG. 2I, bond head manifold 114 is illustrated no longer providing deoxidizing agent 124 and shielding gas 122. In FIG. 2J, bond head assembly 106 is illustrated having been moved away (e.g., along the Z-axis) from support structure 102, with semiconductor element 112 now bonded to substrate 104.

FIGS. 2C-2H illustrate bond head manifold 114 providing deoxidizing agent 124 (e.g., a reducing gas, formic acid, plasma, plasma gas, etc.) and shielding gas 122 (e.g., an inert gas, a gas including nitrogen, etc.) continuously (i.e., prior to and during bonding). However, the invention is not so limited. For example, in certain embodiments, the deoxidizing agent may be provided in contact with contact portions 112a1: just prior to bonding; prior to heating contact portions 112a1; during heating contact portions 112a1; and/or after heating contact portions 112a1.

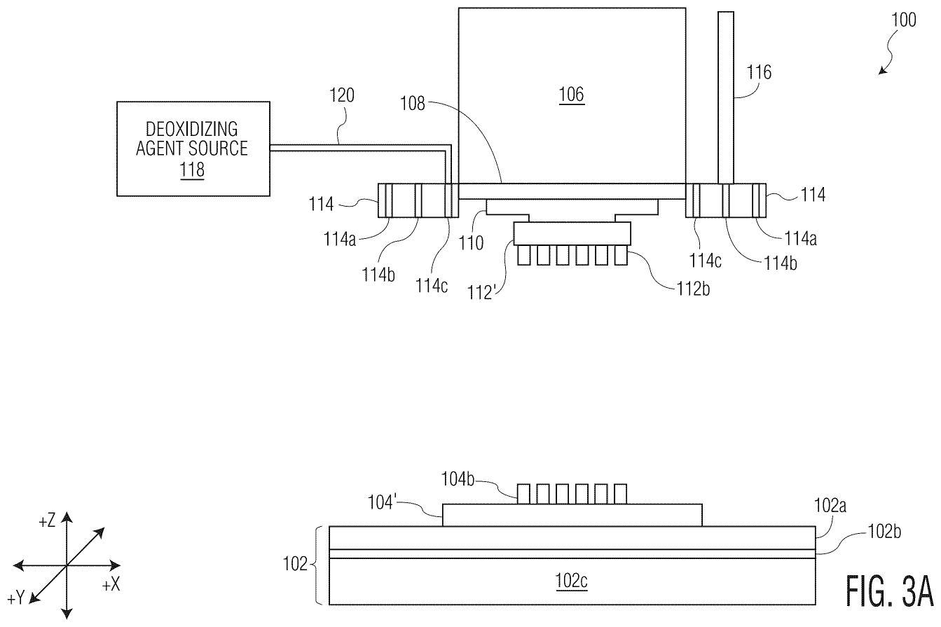

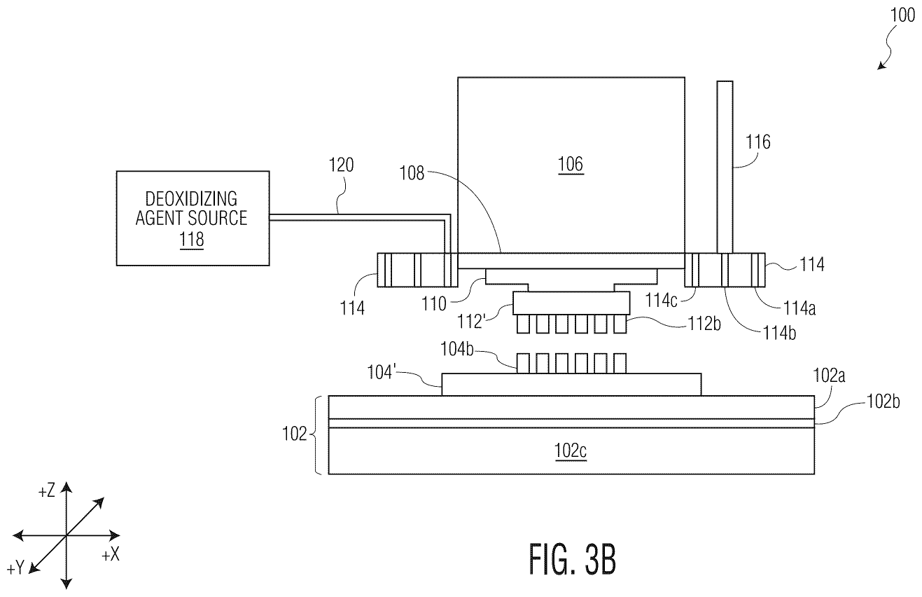

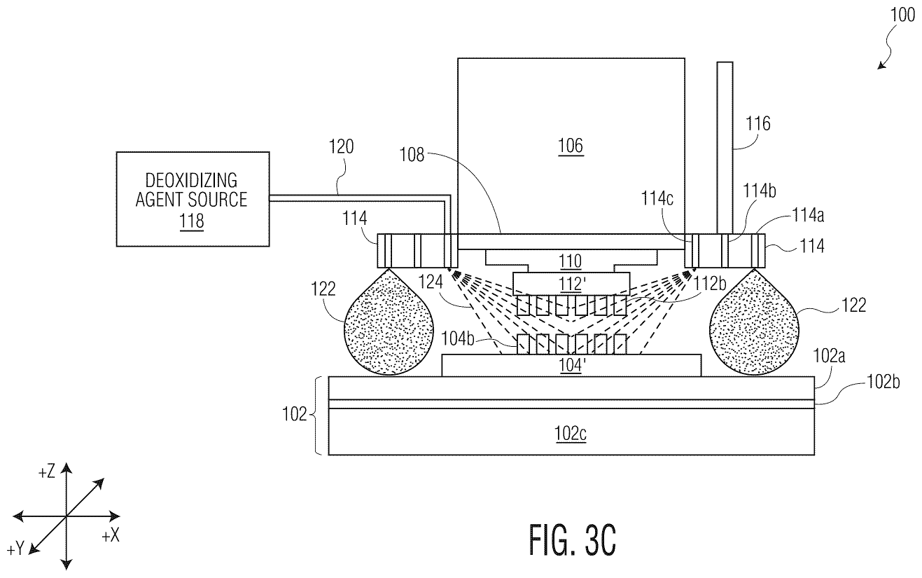

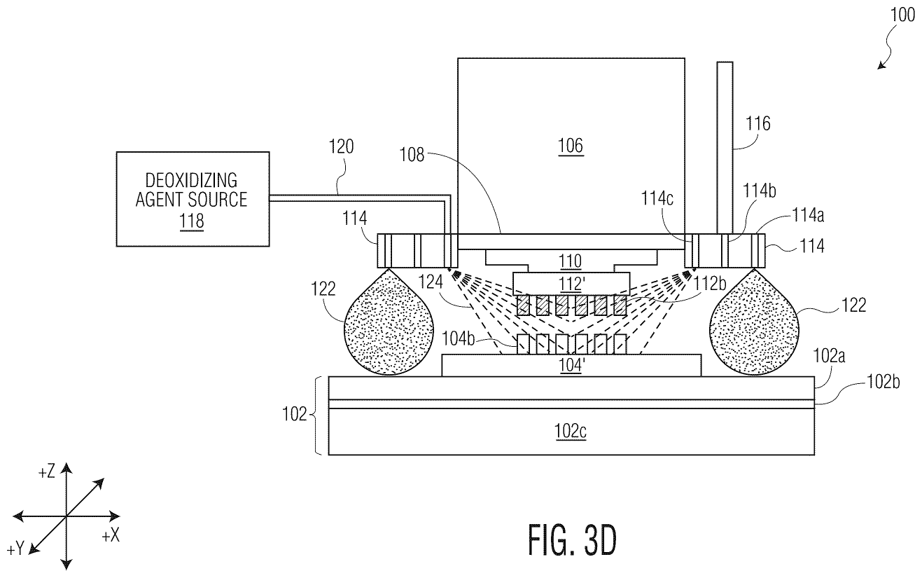

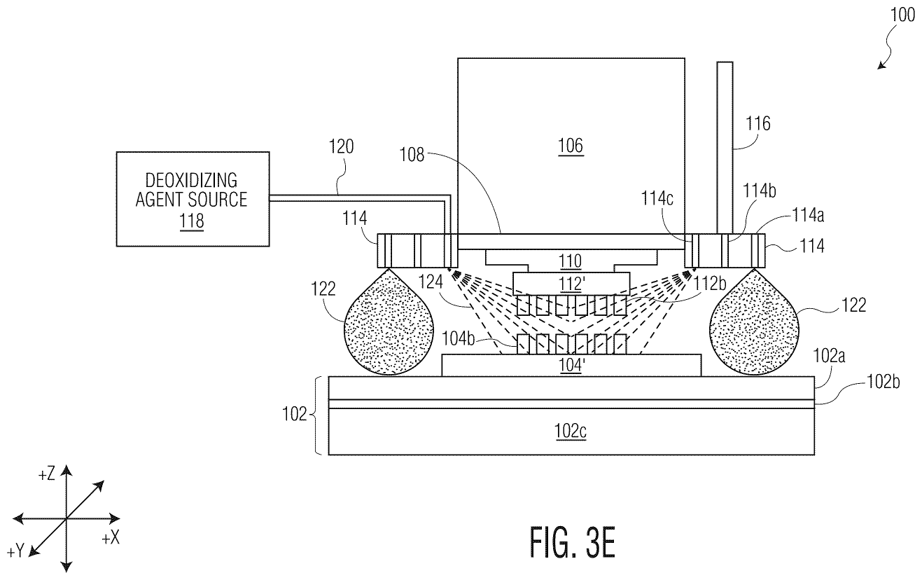

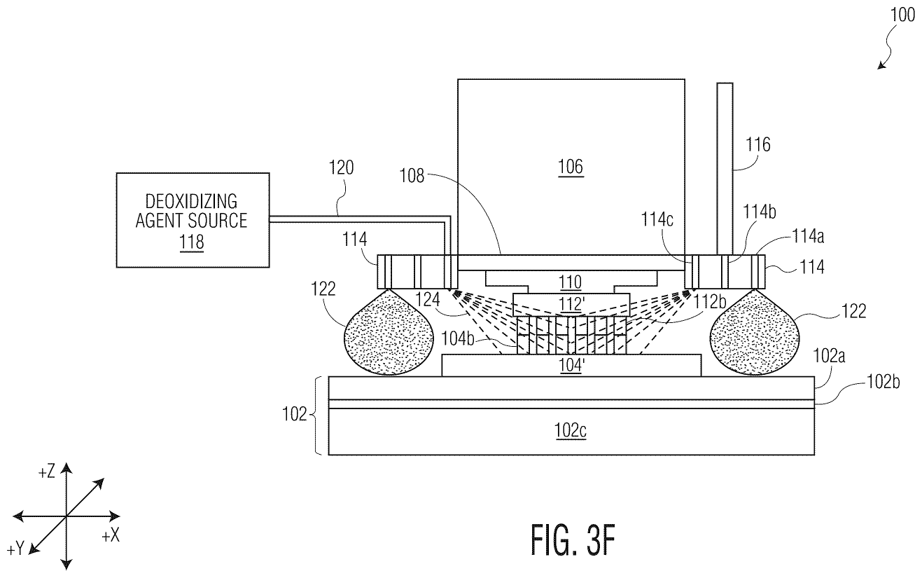

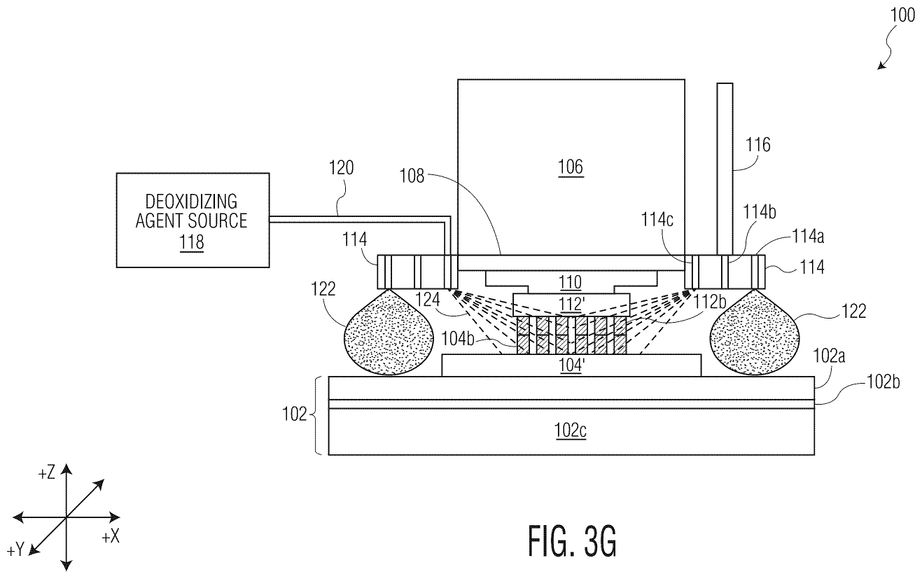

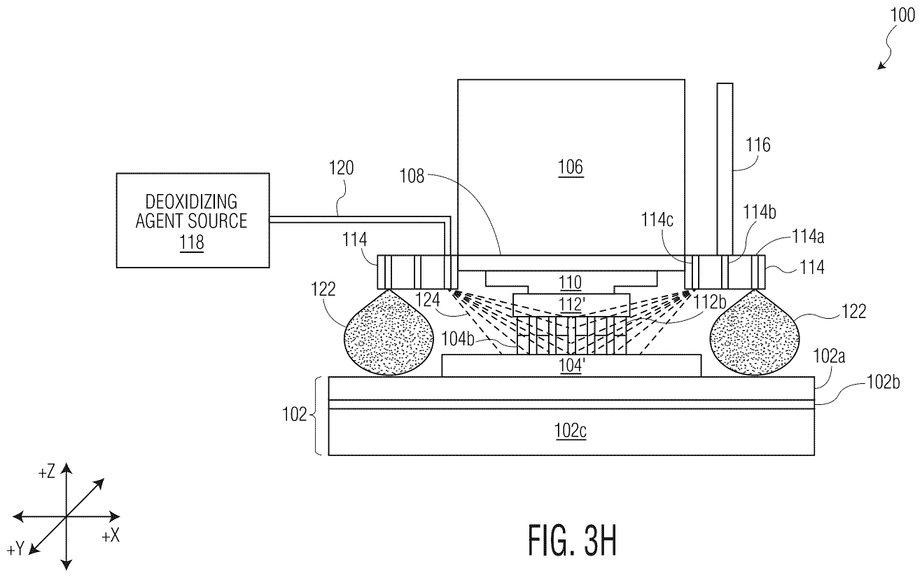

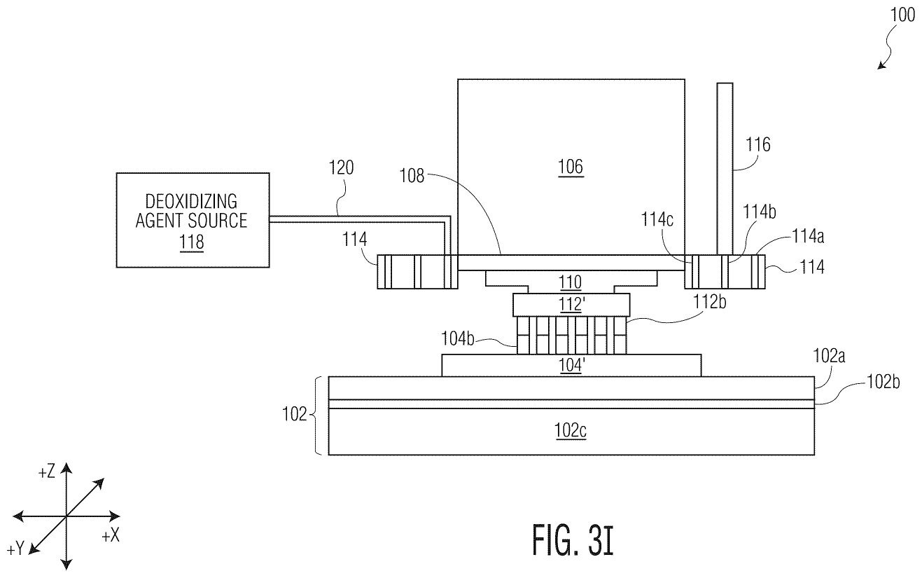

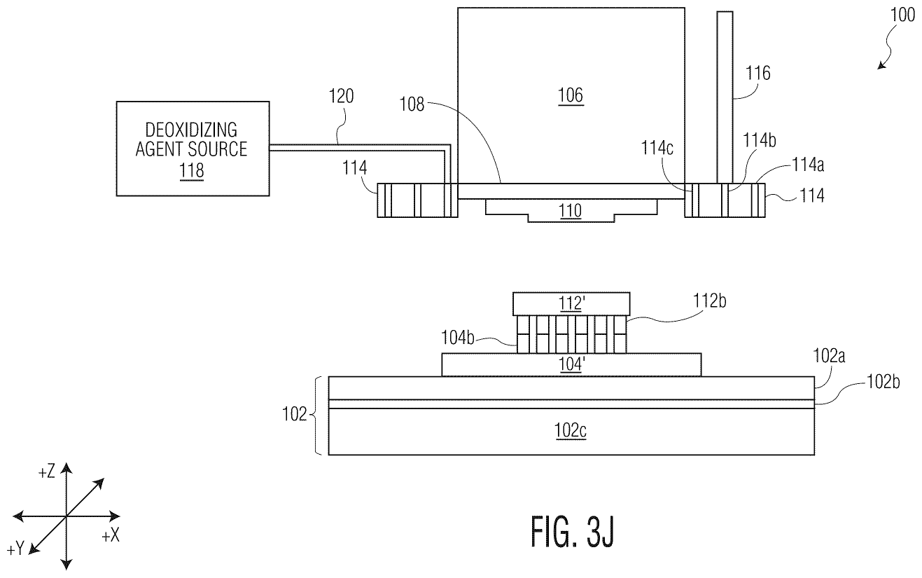

Referring now to FIGS. 3A-3J, another exemplary embodiment of the invention is illustrated. Referring specifically to FIG. 3A, bond head assembly 106 is illustrated positioning semiconductor element 112′ above substrate 104′.

In FIG. 3B, semiconductor element 112′ is provided at a position separated from substrate 104′. Such a position may be considered a post-alignment position, (ii) a pre-bonding position, or (iii) another position (e.g., a predetermined position) as desired. Semiconductor element 112′ includes a plurality of conductive structures 112b. In certain embodiments, conductive structures 112b may include (and/or be made from) copper (e.g., a copper alloy, elemental copper, etc.). Substrate 104′ includes a plurality of conductive structures 104b. In certain embodiments, conductive structures 104b may include (and/or be made from) copper (e.g., a copper alloy, elemental copper, etc.).

In FIG. 3C, bond head manifold 114 is illustrated providing shielding gas 122 and deoxidizing agent 124. Shielding gas 122 (e.g., an inert gas, a gas including nitrogen, etc.) is provided in an area surrounding semiconductor element 112′ and substrate 104′. Deoxidizing agent 124 is illustrated being distributed in proximity to a bonding area of semiconductor element 112′ and substrate 104′. Deoxidizing agent 124 may contact the surfaces of each of the electrically conductive structures 112b of semiconductor element 112′ and each of the electrically conductive structures 104b of substrate 104′.

In FIG. 3D, conductive structures 112b are illustrated at a higher temperature (as indicated by the shading of conductive structures 112b) as compared to conductive structures 112b illustrated in FIG. 3C, while still being in a solid state (e.g., at a temperature below the melting point of a material of conductive structures 112b).

In FIG. 3E, conductive structures 112b are now illustrated at a lower temperature as compared to conductive structures 112b illustrated in FIG. 3D. Accordingly, semiconductor element 112′ (including conductive structures 112b) has now been cooled. In certain embodiments, semiconductor element 112′ may be passively cooled (e.g., via turning off heater 108, via convection of adjacent gases, etc.) and/or actively cooled (e.g., via forced air, via forced gas from a gas channel of heater 108 and/or bonding tool 110, via a cooling mechanism, etc.).

In FIG. 3F, conductive structures 112b are illustrated having been brought into contact with corresponding conductive structures 104b of substrate 104′. Conductive structures 112b may be at a lower temperature as compared to conductive structures 112b illustrated in FIG. 3D and/or FIG. 3E. Conductive structures 104b of substrate 104′ may act as a heatsink or cooling mechanism such that conductive structures 112b are cooled.

In FIG. 3G, conductive structures 112b are now illustrated at a higher temperature (as indicated by the shading of conductive structures 112b) as compared to conductive structures 112b illustrated in FIG. 3F. Further, at least a portion of conductive structures 104b of substrate 104′ are now illustrated at a higher temperature (as indicated by the shading of conductive structures 104b) as compared to conductive structures 104b illustrated in FIG. 3F. In certain embodiments, heat may be provided from heater 108 and/or heater 102b. The elevated temperatures of conductive structures 112b, and of conductive structures 104b, tends to result in a metallurgical bond being formed therebetween.

In FIG. 3H, semiconductor element 112′ has now been bonded to substrate 104′. Each conductive structure 112b (e.g., from FIG. 3G) is illustrated having been bonded to a corresponding conductive structure 104b of substrate 112′. During the bonding operation, corresponding ones of electrically conductive structures 112b of semiconductor element 112′ are bonded (e.g., using heat) to respective ones of electrically conductive structures 104b of substrate 104′. Although six conductive structures 112b of semiconductor element 112′ are illustrated bonded to six conductive structures 104b of substrate 104′, the invention is not so limited. It is understood that any number of conductive structures 112b can be bonded to any number of conductive structures 104b. For example, two or more conductive structures 112b can be bonded to one conductive structure 104b. In another example, two or more conductive structures 104b can be bonded to one conductive structure 112b.

In FIG. 3I, bond head manifold 114 is illustrated no longer providing deoxidizing agent 124 and shielding gas 122. In FIG. 3J, bond head assembly 106 is illustrated having been moved away (e.g., along the Z-axis) from support structure 102, with semiconductor element 112′ now bonded to substrate 104′.

FIGS. 3C-3H illustrate bond head manifold 114 providing deoxidizing agent 124 (e.g., a reducing gas, formic acid, plasma, plasma gas, etc.) and shielding gas 122 (e.g., an inert gas, a gas including nitrogen, etc.) continuously (i.e., prior to and during bonding). However, the invention is not so limited. For example, in certain embodiments, the deoxidizing agent may be provided in contact with contact portions 112b1: just prior to bonding; prior to heating contact portions 112b1; during heating contact portions 112b1; and/or after heating contact portions 112b1.

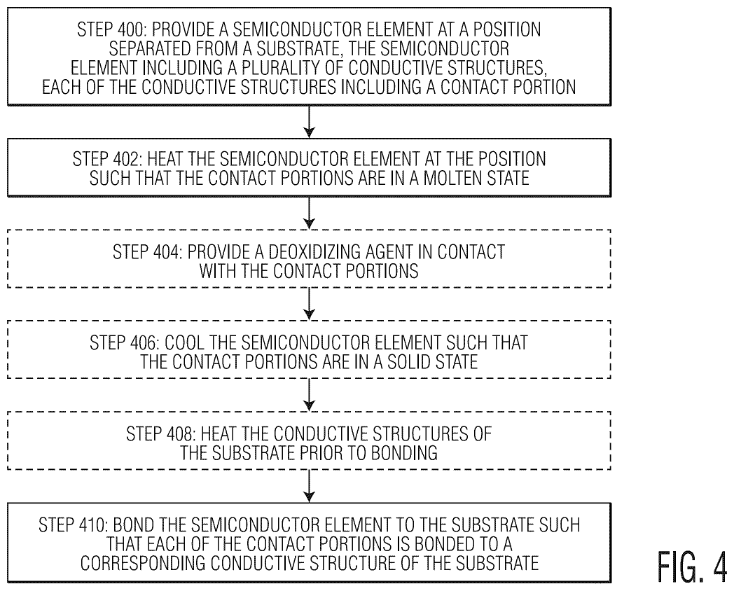

FIGS. 4-7 are flow diagrams illustrating various exemplary methods of bonding a semiconductor element to a substrate. As is understood by those skilled in the art, certain steps included in the flow diagram may be omitted; certain additional steps may be added; and the order of the steps may be altered from the order illustrated—all within the scope of the invention.

Referring specifically to FIG. 4, at Step 400, a semiconductor element is provided at a position separated from a substrate (e.g., see the relative position of semiconductor element 112 and substrate 104 in FIGS. 1B and 2B). The semiconductor element includes a plurality of conductive structures (e.g., conductive structures 112a of FIGS. 1B and 2B), each of the conductive structures including a contact portion (e.g., contact portions 112a1 of FIGS. 1B and 2B). In certain embodiments, the position is a post-alignment position.

At Step 402, the semiconductor element is heated at the position such that the contact portions are in a molten state (e.g., contact portions 112a1 of FIGS. 1D and 2D). In certain embodiments, Step 402 may be before, during, and/or after the semiconductor element is at the position. For example, the semiconductor element may be heated before or while it is moved to the position.

At optional Step 404, a deoxidizing agent (e.g., deoxidizing agent 124 of FIGS. 1C-1G and FIGS. 2C-2H) is provided in contact with the contact portions. In certain embodiments, Step 404 occurs: (i) prior to Step 410; (ii) prior to Step 402; (iii) during Step 402; and/or (iv) after Step 402. In certain embodiments, the deoxidizing agent includes at least one of a reducing gas and a plasma gas. In certain embodiments, the deoxidizing agent includes a reducing gas including formic acid.

At optional Step 406, the semiconductor element is cooled (e.g., after Step 402) such that the contact portions (e.g., contact portions 112a1 of FIG. 2E) are in a solid state (e.g., just prior to Step 410). In certain embodiments, the semiconductor element may be passively cooled and/or actively cooled. At optional Step 408, the conductive structures of the substrate are heated prior to bonding (e.g., conductive structures 104a of substrate 104 of FIGS. 1F and 2G).

At Step 410, the semiconductor element is bonded to the substrate such that each of the contact portions is bonded to a corresponding conductive structure of the substrate (e.g., contact portions 112a1 of FIG. 1F are bonded to conductive structures 104a to form bonded portions 126 of FIG. 1G, contact portions 112a1 of FIG. 2F are bonded to conductive structures 104a to form bonded portions 126 of FIG. 2H).

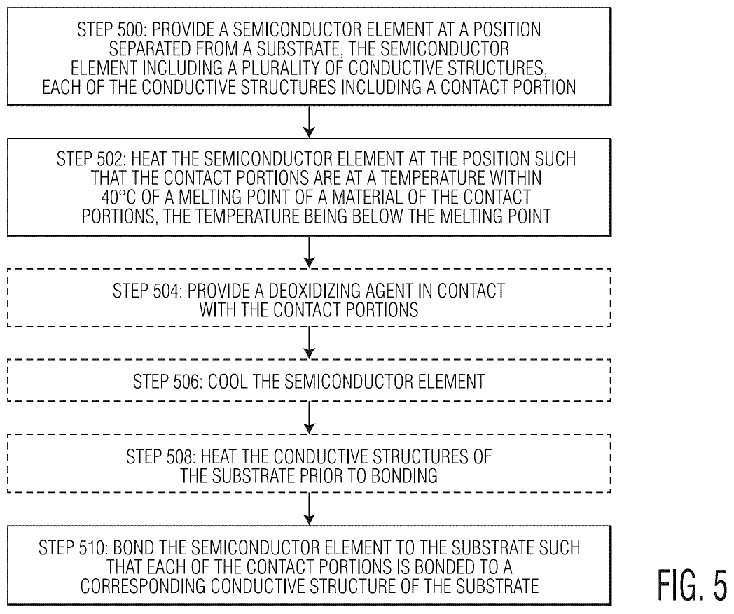

Referring now to FIG. 5, at Step 500, a semiconductor element is provided at a position separated from a substrate (e.g., see the relative position of semiconductor element 112 and substrate 104 in FIGS. 1B and 2B). The semiconductor element includes a plurality of conductive structures (e.g., conductive structures 112a of FIGS. 1B and 2B), each of the conductive structures including a contact portion (e.g., contact portions 112a1 of FIGS. 1B and 2B). In certain embodiments, the position is a post-alignment position.

At Step 502, the semiconductor element is heated at the position such that the contact portions are at a temperature within 40° C. of a melting point of a material of the contact portions (e.g., contact portions 112a1 of FIGS. 1D and 2D). The temperature may be below the melting point (e.g., of a material of the contact portions, such as solder). In certain embodiments, the temperature is: within 30° C. of the melting point; within 20° C. of the melting point; and/or within 10° C. of the melting point. In certain embodiments, Step 502 may be before, during, and/or after the semiconductor element is at the position. For example, the semiconductor element may be heated before or while it is moved to the position.

At optional Step 504, a deoxidizing agent (e.g., deoxidizing agent 124 of FIGS. 1C-1G and FIGS. 2C-2H) is provided in contact with the contact portions. In certain embodiments, Step 504 occurs: (i) prior to Step 510; (ii) prior to Step 502; (iii) during Step 502; and/or (iv) after Step 502. In certain embodiments, the deoxidizing agent includes at least one of a reducing gas and a plasma gas. In certain embodiments, the deoxidizing agent includes a reducing gas including formic acid.

At optional Step 506, the semiconductor element (e.g., including contact portions 112a1 of FIG. 1E) is cooled (e.g., after Step 502). In certain embodiments, the semiconductor element may be passively cooled and/or actively cooled. At optional Step 508, the conductive structures of the substrate are heated prior to bonding (e.g., conductive structures 104a of substrate 104 of FIGS. 1F and 2G).

At Step 510, the semiconductor element is bonded to the substrate such that each of the contact portions is bonded to a corresponding conductive structure of the substrate (e.g., contact portions 112a1 of FIG. 1F are bonded to conductive structures 104a to form bonded portions 126 of FIG. 1G, contact portions 112a1 of FIG. 2F are bonded to conductive structures 104a to form bonded portions 126 of FIG. 2H).

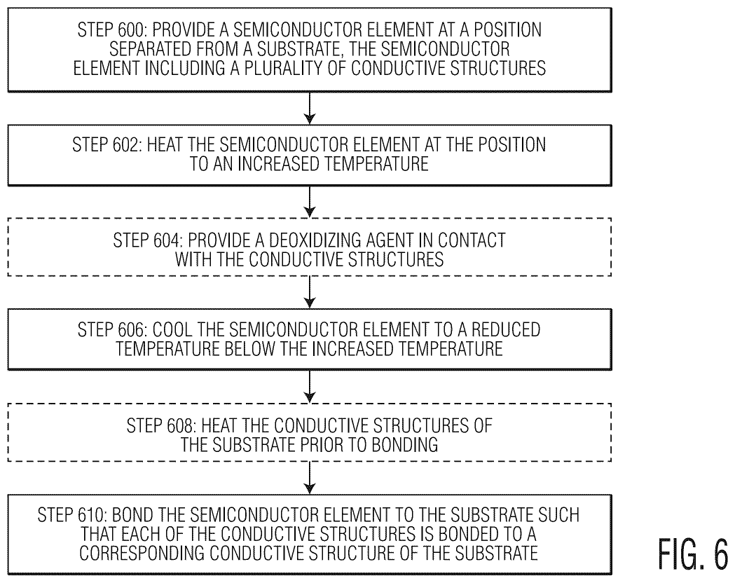

Referring now to FIG. 6, at Step 600, a semiconductor element is provided at a position separated from a substrate (e.g., see the relative position of semiconductor element 112′ and substrate 104′ in FIG. 3B). The semiconductor element includes a plurality of conductive structures (e.g., conductive structures 112b of FIG. 3B). In certain embodiments, the conductive structures of the semiconductor element are made of (and/or include) copper.

At Step 602, the semiconductor element is heated at the position to an increased temperature. In certain embodiments, Step 602 may be before, during, and/or after the semiconductor element is at the position. For example, the semiconductor element may be heated before or while it is moved to the position.

At optional Step 604, a deoxidizing agent (e.g., deoxidizing agent 124 of FIGS. 3C-3H) is provided in contact with the conductive structures (e.g., conductive structures 112b). In certain embodiments, Step 604 occurs: (i) prior to Step 610; (ii) prior to Step 602; (iii) during Step 602; and/or (iv) after Step 602. In certain embodiments, the deoxidizing agent includes at least one of a reducing gas and a plasma gas. In certain embodiments, the deoxidizing agent includes a reducing gas including formic acid.

At Step 606, the semiconductor element is cooled (e.g., after Step 602) to a reduced temperature below the increased temperature (e.g., semiconductor element 112′ of FIG. 3E). In certain embodiments, the semiconductor element may be passively cooled and/or actively cooled. At optional Step 608, the conductive structures of the substrate are heated prior to bonding (e.g., conductive structures 104b of FIG. 3G). At Step 610, the semiconductor element is bonded to the substrate such that each of the conductive structures is bonded to a corresponding conductive structure of the substrate (e.g., see bonded semiconductor element 112′ of FIG. 3I).

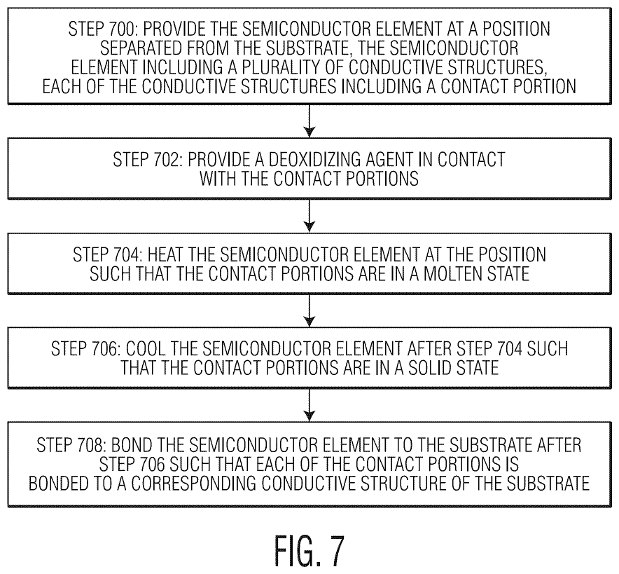

Referring now to FIG. 7, at Step 700, the semiconductor element (e.g., semiconductor element 112 of FIG. 1B) is provided at a position (e.g., a post-alignment position) separated from the substrate (e.g., substrate 104 of FIG. 1B). The semiconductor element includes a plurality of conductive structures, each of the conductive structures including a contact portion (e.g., contact portions 112a1 of FIG. 1B).

At Step 702, a deoxidizing agent (e.g., deoxidizing agent 124 of FIG. 1C) is provided in contact with the contact portions. In certain embodiments, Step 702 occurs prior to bonding (e.g., Step 708). In certain embodiments, Step 702 occurs prior to heating the semiconductor element (e.g., Step 704). In certain embodiments, the deoxidizing agent includes at least one of a reducing gas and a plasma gas. In certain embodiments, the deoxidizing agent includes a reducing gas including formic acid (e.g., formic acid vapor).

At Step 704, the semiconductor element is heated at the position such that the contact portions are in a molten state (e.g., contact portions 112a1 of FIG. 1D). At Step 706, the semiconductor element is cooled (e.g., after Step 704) such that the contact portions (e.g., contact portions 112a1 of FIG. 1E) are in a solid state (e.g., just prior to Step 708).

At Step 708, the semiconductor element is bonded to the substrate after Step 706 such that each of the contact portions is bonded to a corresponding conductive structure of the substrate (e.g., contact portions 112a1 of FIG. 1F bonding to conductive structures 104a to form bonded portions 126 of FIG. 1G). In certain embodiments, a step of heating the conductive structures of the substrate occurs prior (e.g., just prior) to Step 708.

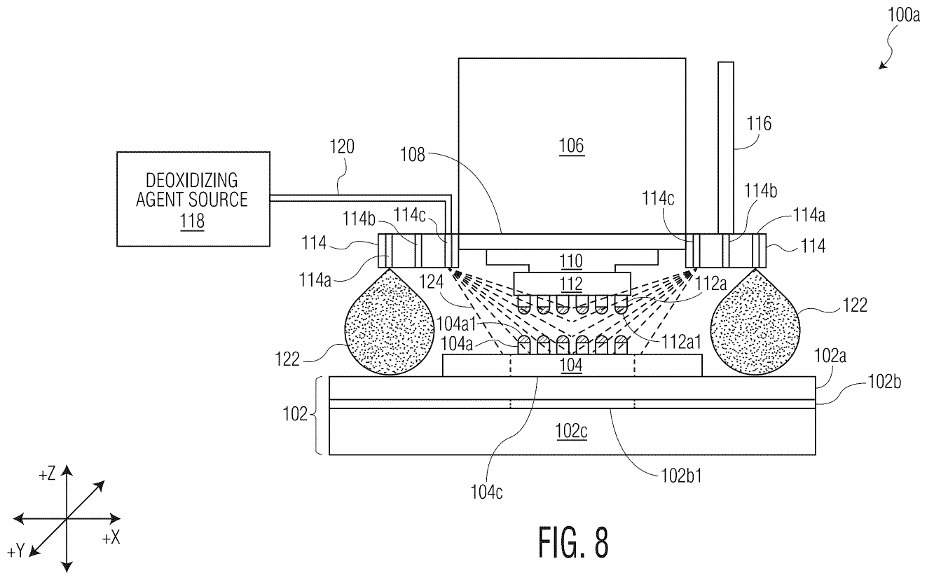

Various exemplary aspects of the invention are described with respect to heating a semiconductor element at a position separated from a substrate. The heat may be provided, for example, by a heater (e.g., heater 108) included in a bond head assembly. For example, such a heater may heat the semiconductor element at the position such that contact portions of conductive structures of the semiconductor element are in a molten state. In another example, such a heater may heat the semiconductor element at the position such that the contact portions are at a temperature within 40° C. of a melting point of a material of the contact portions, the temperature being below the melting point. In yet another example, such a heater may heat the semiconductor element to an increased temperature at the position, where the semiconductor element is cooled after the heating (and prior to bonding) to a reduced temperature below the increased temperature. It should be understood that instead of (or in addition to) the semiconductor element being heated in these exemplary ways, the substrate (or a portion of the substrate) may be heated. FIG. 8 illustrates a bonding system 100a which is the same as previously described bonding systems (with the same reference numerals) except as described herein. Bonding system 100a includes a localized heater 102b1 (e.g., a laser source, a pulsed laser source, etc.) for heating a local portion 104c of substrate 104. That is, local portion 104c may be a portion of substrate 104 configured to receive semiconductor element 112 in a bonding process. It may be desirable to heat the conductive structures 104a (e.g., in particular, contact portions 104a1 of such conductive structures 104a) in the presence of deoxidizing agent 124. For example: to heat the substrate 104 at the position such that contact portions 104a1 are in a molten state; to heat the substrate 104 at the position such that contact portions 104a1 are at a temperature within 40° C. of a melting point of a material of the contact portions (the temperature being below the melting point); or to heat the substrate to an increased temperature at the position, where the substrate is cooled after the heating (and prior to bonding) to a reduced temperature below the increased temperature. Such heating operations may be accomplished using localized heater 102b1, or another heating source as desired. The heating operation described in this paragraph with regard to contact portions 104a1 of substrate 104 may be implemented in combination with (or instead of) any other embodiment of the invention, for example, as illustrated and described in connection with FIGS. 1A-1I, FIGS. 2A-2J, FIGS. 3A-3J, and FIGS. 4-7.

Although the invention is illustrated and described primarily with respect to a deoxidizing agent distributed through a bond head assembly, it is not limited thereto. As will be appreciated by those skilled in the art, a deoxidizing agent may be provided in a number of different configurations, such as, for example, through a support structure configured to support a substrate. More specifically, as shown in U.S. Pat. No. 11,205,633 (see FIGS. 11A-11D therein), a reducing gas (i.e., an example of a deoxidizing agent described herein) may be provided through a support structure.

Although not explicitly described in connection with the various embodiments of the invention disclosed herein, during bonding of a semiconductor element to a substrate, ultrasonic energy and/or force may be utilized, as is known to those skilled in the art.

Although the invention is illustrated and described herein with reference to specific embodiments, the invention is not intended to be limited to the details shown. Rather, various modifications may be made in the details within the scope and range of equivalents of the claims and without departing from the invention.
Claimed:

1. A method of bonding a semiconductor element to a substrate, the method comprising the steps of:
(a) providing the semiconductor element at a position separated from the substrate, the semiconductor element including a plurality of conductive structures, each of the conductive structures including a contact portion;
(b) heating the semiconductor element at the position such that the contact portions are in a molten state; and
(c) bonding the semiconductor element to the substrate such that each of the contact portions is bonded to a corresponding conductive structure of the substrate.

2. The method of claim 1 further comprising a step of providing a deoxidizing agent in contact with the contact portions prior to step (c).

3. The method of claim 1 further comprising a step of providing a deoxidizing agent in contact with the contact portions prior to step (b).

4. The method of claim 1 further comprising a step of providing a deoxidizing agent in contact with the contact portions during step (b).

5. The method of claim 1 further comprising a step of providing a deoxidizing agent in contact with the contact portions after step (b).

6. The method of claim 1 further comprising a step of cooling the semiconductor element after step (b) such that the contact portions are in a solid state just prior to step (c).

7. The method of claim 1 wherein the position is a post-alignment position.

8. The method of claim 1 further comprising a step of heating the conductive structures of the substrate prior to step (c).

9. The method of claim 2 wherein the deoxidizing agent includes at least one of a reducing gas and a plasma gas.

10. The method of claim 2 wherein the deoxidizing agent includes a reducing gas, the reducing gas including formic acid.

11. A method of bonding a semiconductor element to a substrate, the method comprising the steps of:
(a) providing the semiconductor element at a position separated from the substrate, the semiconductor element including a plurality of conductive structures, each of the conductive structures including a contact portion;
(b) heating the semiconductor element at the position such that the contact portions are at a temperature within 40° C. of a melting point of a material of the contact portions, the temperature being below the melting point; and
(c) bonding the semiconductor element to the substrate such that each of the contact portions is bonded to a corresponding conductive structure of the substrate.

12. The method of claim 11 further comprising a step of providing a deoxidizing agent in contact with the contact portions prior to step (c).

13. The method of claim 11 further comprising a step of providing a deoxidizing agent in contact with the contact portions prior to step (b).

14. The method of claim 11 further comprising a step of providing a deoxidizing agent in contact with the contact portions during step (b).

15. The method of claim 11 further comprising the step of providing a deoxidizing agent in contact with the contact portions after step (b).

16. The method of claim 11 further comprising a step of cooling the semiconductor element after step (b).

17. The method of claim 11 wherein the position is a post-alignment position.

18. The method of claim 11 further comprising a step of heating the conductive structures of the substrate prior to step (c).

19. The method of claim 12 wherein the deoxidizing agent includes at least one of a reducing gas and a plasma gas.

20. The method of claim 12 wherein the deoxidizing agent includes a reducing gas, the reducing gas including formic acid.

21. The method of claim 11 wherein step (b) includes heating the semiconductor element at the position such that the contact portions are within 30° C. of the melting point.

22. The method of claim 11 wherein step (b) includes heating the semiconductor element at the position such that the contact portions are within 20° C. of the melting point.

23. The method of claim 11 wherein step (b) includes heating the semiconductor element at the position such that the contact portions are within 10° C. of the melting point.

24. A method of bonding a semiconductor element to a substrate, the method comprising the steps of:
(a) providing the semiconductor element at a position separated from the substrate, the semiconductor element including a plurality of conductive structures;
(b) heating the semiconductor element at the position to an increased temperature;
(c) cooling the semiconductor element after step (b) to a reduced temperature below the increased temperature; and
(d) bonding the semiconductor element to the substrate such that each of the conductive structures is bonded to a corresponding conductive structure of the substrate.

25. The method of claim 24 further comprising a step of providing a deoxidizing agent in contact with the conductive structures prior to step (d).

26. The method of claim 24 further comprising a step of providing a deoxidizing agent in contact with the conductive structures prior to step (b).

27. The method of claim 24 further comprising a step of providing a deoxidizing agent in contact with the conductive structures during step (b).

28. The method of claim 24 further comprising a step of providing a deoxidizing agent in contact with the conductive structures after step (b).

29. The method of claim 24 wherein the position is a post-alignment position.

30. The method of claim 24 further comprising a step of heating the conductive structures of the substrate prior to bonding.

31. The method of claim 25 wherein the deoxidizing agent includes at least one of a reducing gas and a plasma gas.

32. The method of claim 25 wherein the deoxidizing agent includes a reducing gas, the reducing gas including formic acid.

33. The method of claim 24 wherein the conductive structures of the semiconductor element include copper.

34. The method of claim 33 wherein the conductive structures of the substrate include copper.

35. The method of claim 24 wherein the conductive structures of the substrate include copper.

36. The method of claim 24 wherein no solder is provided between the conductive structures and the corresponding conductive structures of the substrate during step (d).

37. A method of bonding a semiconductor element to a substrate, the method comprising the steps of:
(a) providing the semiconductor element at a position separated from the substrate, the semiconductor element including a plurality of conductive structures, each of the conductive structures including a contact portion;
(b) providing a deoxidizing agent in contact with the contact portions;
(c) heating the semiconductor element at the position such that the contact portions are in a molten state;
(d) cooling the semiconductor element after step (c) such that the contact portions are in a solid state; and
(e) bonding the semiconductor element to the substrate after step (d) such that each of the contact portions is bonded to a corresponding conductive structure of the substrate.

38. The method of claim 37 wherein step (b) occurs prior to step (e).

39. The method of claim 37 wherein step (b) occurs prior to step (c).

40. The method of claim 37 wherein step (d) occurs after step (c) such that the contact portions are in a solid state just prior to step (e).

41. The method of claim 37 wherein the position is a post-alignment position.

42. The method of claim 37 further comprising a step of heating the conductive structures of the substrate prior to step (e).

43. The method of claim 37 wherein the deoxidizing agent includes at least one of a reducing gas and a plasma gas.

44. The method of claim 37 wherein the deoxidizing agent includes a reducing gas, the reducing gas including formic acid.
